(19) United States
(12) Patent Application Publication
(10) Pub. No.: US 2025/0351654 A1
(43) Pub. Date: Nov. 13, 2025

(54) OPTOELECTRONIC DEVICE FOR LUMINOUS DISPLAY AND MANUFACTURING METHOD

(71) Applicant: ALEDIA, ÉCHIROLLES (FR)

(72) Inventors: Ivan-Christophe ROBIN, Grenoble (FR); Frédéric MAYER, Voiron (FR); Erwan DORNEL, Champagnier (FR); Frédéric MERCIER, Saint Nicolas de Macherin (FR)

(21) Appl. No.: 18/008,060

(22) PCT Filed: May 31, 2021
(86) PCT No.: PCT/FR2021/050976

§ 371 Date: Jun. 20, 2023

(30) Foreign Application Priority Data
Jun. 3, 2020 (FR) FR2005795

(51) Int. Cl. H10H 29/85; H01L 25/16; H10H 29/01

(52) U.S. Cl. CPC H10H 29/857; H01L 25/167; H10H 29/0364

(57) ABSTRACT

An optoelectronic device for a light display including: a support; a light element with at least one first electrode; primary conductive elements; and secondary conductive elements. The device further includes a first electrically insulating element, wherein for said at least one light element, at least one first connecting portion of at least one of the secondary conductive elements corresponding to the light element is formed in all or part of a first imprint obtained in the first electrically insulating element. The first connecting portion of the secondary conductive element is in contact with the first electrode.

### CROSS REFERENCE TO RELATED APPLICATIONS

This application is a National Stage of PCT Application No. PCT/FR2021/050976 filed on May 31, 2021, which claims priority to French Patent Application No. FR2005795, filed on Jun. 3, 2020, the contents of each of which are incorporated herein by reference thereto.

### TECHNICAL FIELD The present disclosure concerns an optoelectronic device for a light display, comprising:

a support delimiting a support face,
at least one light element having a thickness considered in a transverse direction oriented transversely to the support, fastened to the support face via a fastening element, and comprising at least one first electrode, at least one second electrode electrically insulated from the first electrode, and at least one light emission part capable of emitting light when a current passes through the light emission part and comprising at least one light-emitting diode,
a plurality of primary conductive elements electrically insulated from each other, at least one of the primary conductive elements electrically connecting at least said second electrode,
a plurality of secondary conductive elements electrically insulated from each other and electrically insulated from the primary conductive elements, at least one of the secondary conductive elements electrically connecting at least said first electrode.

The disclosure also concerns a method for manufacturing an optoelectronic device for a light display.

### BACKGROUND

In the field of light display screens with micrometric light-emitting diodes, the light elements constituting the screen must be arranged in a matrix manner. The accuracy required for the formation of such a matrix increases as the resolution expected for screens increases.

It is known to produce the light-emitting diodes which constitute the light elements on a first support, for example a silicon or sapphire wafer, and to transfer them to a second support intended to form an integral part of the screen. The electrical connections that allow electrically powering the light-emitting diodes thus transferred are made at the level of the second support.

In the case where the light-emitting diodes are separated by a distance of less than about ten microns, the electrical connection of the upper part of the light-emitting diodes and the electrical connection of their lower part remain difficult to achieve without risk of involuntary short-circuit, due to the short distance between them.

In the case where the light-emitting diodes are three-dimensional, typically of wire shape which is a very advantageous shape, obtaining an electrical connection of their upper part is difficult due to their micrometric or even nanometric dimensions. An additional problem encountered during the transfer of the light elements is that the accurate positioning of the light elements at the level of the second support is not guaranteed because of the increasingly small dimensions of the light elements and the electrical connections to obtain the best possible resolution for the light display proposed by the optoelectronic device. The conventional techniques for recovering the electrical contacts on the light elements are not satisfactory because the positioning faults are random and according to an error range that is too high relative to the dimensions of the light elements and the electrical connections.

### SUMMARY

The present disclosure aims to provide an optoelectronic device and a manufacturing method making it possible to address all or part of the problems presented above.

In particular, an aim is to provide a solution that meets at least one of the following advantages:
to allow providing of an optoelectronic device for a light display limiting the risks of short-circuit;
to allow providing of an optoelectronic device for a light display at lower cost;
to allow providing of an optoelectronic device for a light display having large dimensions;
to allow providing of an optoelectronic device for a light display having high performance and the highest possible display resolution;
to allow providing of an optoelectronic device in which the majority of the light elements are electrically connected in a satisfactory manner.

This aim can be achieved thanks to an optoelectronic device for a light display, comprising:
a support delimiting a support surface;
at least one light element having a thickness H considered in a transverse direction oriented transversely to the support, fastened to the support surface via a fastening element, and comprising at least one first electrode, at least one second electrode electrically insulated from the first electrode, and at least one light emission part capable of emitting light when a current passes through the light emission part and comprising at least one light-emitting diode;
a plurality of primary conductive elements electrically insulated from each other, at least one of the primary conductive elements electrically connecting at least said second electrode;
a plurality of secondary conductive elements electrically insulated from each other and electrically insulated from the primary conductive elements at least one of the secondary conductive elements electrically connecting at least said first electrode; each light element delimits externally, along the thickness H, at least one lateral wall which extends laterally around the light element; the optoelectronic device comprising at least one first electrically insulating element arranged at least in part around said at least one lateral wall of the light element and between at least one of the secondary conductive elements and at least one of the primary conductive elements so that said at least one secondary conductive element and said at least one primary conductive element separated by the first electrically insulating element are electrically insulated from each other,
for said at least one light element, at least one first connecting portion of at least one of the secondary conductive elements corresponding to said light element is formed in all or part of a first imprint obtained in the first electrically insulating element, at least one part of the first imprint being superimposed on the first electrode so that at least the first connecting portion of the secondary conductive element is in contact with the first electrode.

Some preferred but non-limiting aspects of the optoelectronic device are as follows.

In one implementation of the device, the support, at least one of the primary conductive elements and the fastening element are at least partially transparent to the light emitted by the light emission part of the light elements.

In one implementation of the device, said light element includes an upper portion comprising the light emission part and a lower portion including a control device connected to at least one of the light-emitting diodes of the light emission part and capable of modulating at least one emission parameter of the light emission part.

In one implementation of the device, the light-emitting diode is wire-shaped with micrometric dimensions and whose main axis of extension is overall parallel to said transverse direction.

In one implementation of the device, the lateral wall extends laterally around at least the lower portion and the upper portion.

In one implementation of the device, all or part of the primary conductive element is formed on the support surface.

In one implementation of the device, the second electrode of at least one of the light elements is formed on the support surface side.

In one implementation of the device, the first imprint is formed by an adaptive photolithography method.

In one implementation of the device the device comprises a plurality of light elements fastened to the support face, the first connecting portions of the secondary conductive elements formed in the first corresponding imprints, have respective spatial configurations which differ from one first connecting portion to another and in this implementation, the spatial configuration adopted by each first connecting portion depends on the positioning of the light element with which it is in contact relative to the support.

In one implementation of the device, at the level of at least one of the light elements, all or part of the primary conductive element is formed in a second imprint obtained in the first electrically insulating element, at least one part of the second imprint being superimposed on the location of the second electrode so that a second connecting portion of the primary conductive element is in contact with the second electrode.

In one implementation of the device, all or part of the second imprint is formed by an adaptive photolithography method.

In one implementation of the device, for the different light elements of the plurality, the second connecting portions of the primary conductive elements have respective spatial configurations which differ from a second connecting portion to another and in this implementation the spatial configuration adopted by each second connecting portion depends on the positioning of the light element with which it is in contact relative to the support.

In one implementation of the device, each secondary conductive element comprises at least one first main portion in contact with the first connecting portion, the first main portion being a member dissociated from the first connecting portion, and in this implementation, each primary conductive element comprises at least one second main portion in contact with the second connecting portion, the second main portion being a member dissociated from the second connecting portion.

In one implementation of the device, at least one part of a portion selected from the group comprising the first main portion of one of the secondary conductive elements and the second main portion of one of the primary conductive elements is formed on an upper surface of the first electrically insulating element arranged opposite to the support surface of the support in the transverse direction.

In one implementation of the device, at least one part of one of the primary conductive elements is arranged in contact with the support surface of the support.

In one implementation of the device, the fastening element comprises a set of metal particles coated in an electrically insulating material adapted so that the electrically insulating material is capable of varying between a first state of electrical insulation in which the electrically insulating material does not undergo collapsing pressure and where a majority of the metal particles do not touch each other and a second state of anisotropic electrical conductivity in which a majority of the metal particles are in electrical contact under the effect of a collapsing pressure applied in the transverse direction.

In one implementation of the device, the fastening element is an adhesive having properties of transparency for the light emitted by the light emission part of the light element fastened by said fastening element. In one implementation of the device, the light element(s) are obtained on an external support different from the support prior to a transfer of said light elements to the support surface of the support.

In one implementation of the device, the fastening element is electrically conductive.

In one implementation of the device, said at least one second electrode is arranged projecting from the light element.

The disclosure also relates to the implementation of a method for manufacturing an optoelectronic device for a light display, the manufacturing method comprising the following steps:
E1) provide a support delimiting a support surface;
E2) form at least one light element having a thickness considered in a transverse direction oriented transversely to the support, fastened to the support surface via a fastening element, and comprising at least one first electrode and at least one second electrode electrically insulated from each other, in which said at least one light element delimits externally, along the thickness, at least one lateral wall which extends laterally around the light element, said at least one light element formed in step E2) including at least one light emission part capable of emitting light when a current passes through the light emission part and comprising at least one light-emitting diode;
E3) form a plurality of primary conductive elements electrically insulated from each other, at least one of the primary conductive elements being electrically connected to at least said second electrode;
E4) form at least one first electrically insulating element arranged at least in part around said at least one lateral wall,
E5) form a plurality of secondary conductive elements, electrically insulated from each other, at least one of the secondary conductive elements being electrically connected to at least said first electrode;

the manufacturing method wherein at the end of step E5), the first electrically insulating element is arranged between at least one of the primary conductive elements and at least one of the secondary conductive elements so that said at least one secondary conductive element and said at least one primary conductive element separated by the first electrically insulating element are electrically insulated from each other and wherein step E5) comprises the following sub-steps:
E51) tracking of a current position of the first electrode of said at least one light element by a tracking device;
E52) determination of local photolithography parameters by an adjustment device taking into account the current position of the first electrode of the light element determined in step E51);
E53) formation, using at least one photolithography beam adjusted at least in part with the local photolithography parameters determined in step E52), of all or part of a first imprint in the first electrically insulating element, such that at least one part of the first imprint is superimposed on the first electrode;
E54) formation of at least one first connecting portion of the secondary conductive element in said first imprint so that at least the first connecting portion of said at least one secondary conductive element is in contact with the first electrode.

In one implementation of the method, step E5) comprises a sub-step E55) consisting in forming a first main imprint in the first electrically insulating element and opening onto the first imprint, by a method different from the method used in steps E51) to E53).

In one implementation of the method, step E5) comprises an additional sub-step E56) consisting in forming in the first main imprint a first main portion of the secondary conductive element, in contact with the first connecting portion.

In one implementation of the method, step E2) includes a sub-step E21) consisting in obtaining said at least one light element on an external support different from the support prior to a transfer of said light element towards the support surface of the support by fastening thanks to the fastening element.

### BRIEF DESCRIPTION OF THE DRAWINGS

Other aspects, aims, advantages and features of the disclosure will better appear on reading the following detailed description of preferred embodiments thereof, given as a non-limiting example, and made with reference to the appended drawings in which:

FIG. 1 is a schematic sectional view of several steps of a manufacturing method according to the disclosure allowing obtaining an example of an optoelectronic device according to the disclosure where a secondary conductive element is arranged on the upper surface of the first insulating element and in contact with a light element and where a primary conductive element is arranged on the support face.

FIG. 2 is a schematic sectional view of several steps of a manufacturing method according to the disclosure allowing obtaining an example of an optoelectronic device according to the disclosure where a secondary conductive element is arranged on the upper surface of the first insulating element and in contact with a light element whose second electrode is projecting and where a primary conductive element is arranged on the support face.

FIG. 3 is a schematic sectional view of several steps of a manufacturing method according to the disclosure allowing obtaining an example of an optoelectronic device according to the disclosure where the secondary conductive elements are arranged on the upper surface of the first insulating element in contact with the first electrode of two light elements and the primary conductive elements are arranged on the support face.

FIG. 4 is a schematic sectional view of several steps of a manufacturing method according to the disclosure allowing obtaining an example of an optoelectronic device according to the disclosure where the secondary conductive elements are arranged in part on the support face and the primary conductive elements are arranged on the support face.

FIG. 5 is a schematic sectional view of several steps of a manufacturing method according to the disclosure allowing obtaining an example of an optoelectronic device according to the disclosure where the secondary conductive elements and the primary conductive elements are arranged on the upper surface of the first insulating element.

FIG. 6 is a schematic sectional view of several steps of a manufacturing method according to the disclosure allowing obtaining an example of an optoelectronic device according to the disclosure where the secondary conductive elements are arranged on the upper surface of the first insulating element and the primary conductive elements are arranged in part on the upper surface of the first insulating element and in part on the support face.

FIG. 7 is a schematic top view of an example of an optoelectronic device according to the disclosure where the first connecting portions of the secondary conductive elements have respective spatial configurations which differ from one first connecting portion to another and where the spatial configuration adopted by each first connecting portion depends on the positioning of the light element with which it is in contact relative to the support, the first electrically insulating element being not represented.

FIG. 8 is a schematic top view of an example of an optoelectronic device according to the disclosure where the primary and secondary conductive elements are parallel, the first electrically insulating element being not represented.

FIG. 9 is a schematic top view of an example of an optoelectronic device according to the disclosure where the first main portion of one of the secondary conductive elements and the second main portion of one of the primary conductive elements are formed on the upper surface of the first electrically insulating element.

### DETAILED DESCRIPTION OF THE DRAWINGS

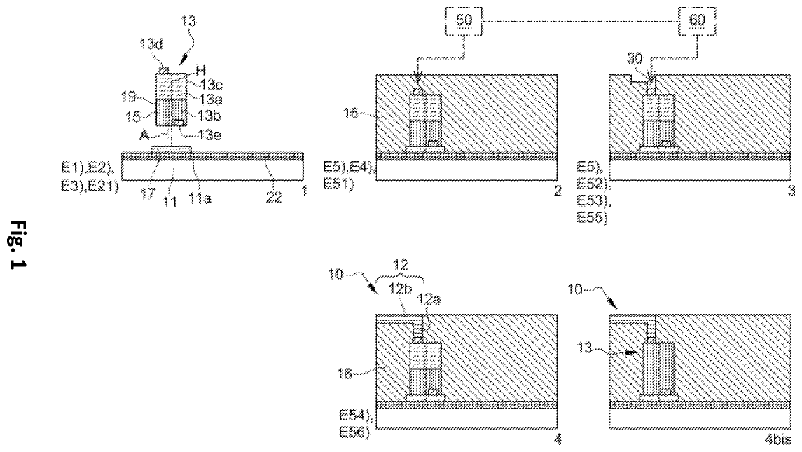

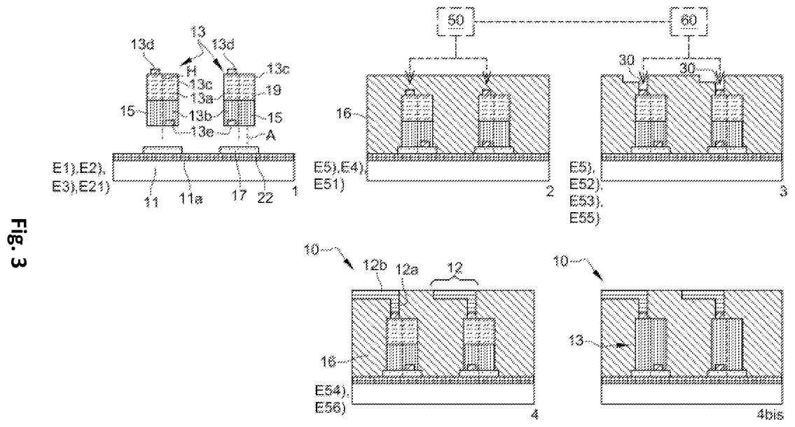

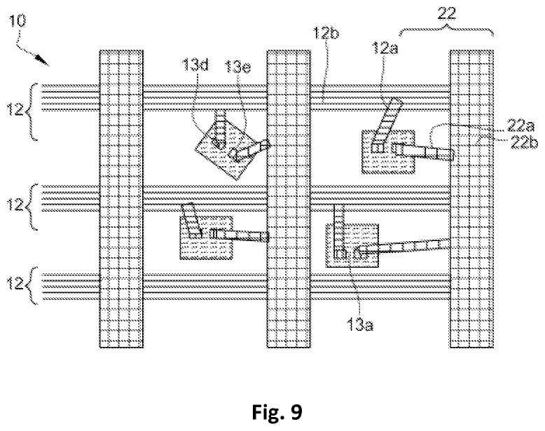

In the appended FIGS. 1 to 9 and in the following description, elements which are functionally identical or similar are identified by the same references. In addition, the different elements are not represented to scale so as to favor the clarity of the figures for ease of understanding. Furthermore, the different embodiments and variants are not mutually exclusive and may, on the contrary, be combined with each other.

In the following description, unless otherwise indicated, the terms “substantially”, “approximately”, “overall” and “in the order of” mean “within 10%”.

The disclosure relates firstly to an optoelectronic device for a light display. As illustrated in FIGS. 1 to 6, the device comprises a support 11 delimiting a support surface 11a. The lower support 11 is, for example, electrically insulating and formed by one or several glass plates. The support 11 can also be, on parts, electrically conductive and formed on these parts by one or several metal plates. The support 11 can also comprise conductive tracks insulated from each other and formed at the surface thereof or therein. The support 11 can be crystalline or non-crystalline and also include active or passive components such as transistors or memories. The support 11 can for example constitute a support for a light display screen.

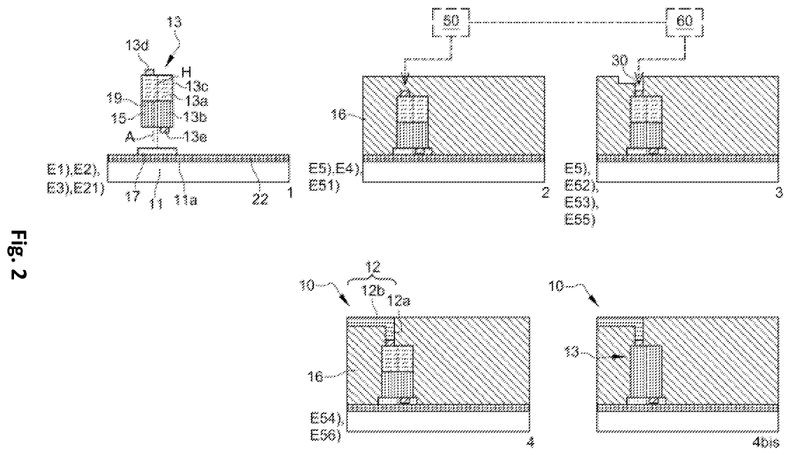

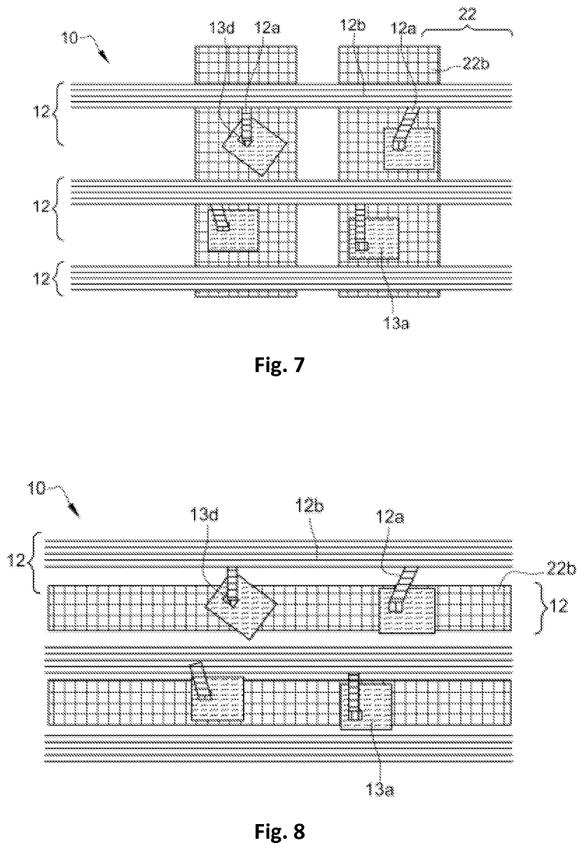

The device also comprises at least one light element 13. It is possible to produce a light display from a single light element 13 as shown in FIGS. 1 and 2, however, for example, in order to produce a display screen, it is also possible to provide for a plurality of light elements 13 arranged, for example, in a matrix arranged more or less regularly as illustrated in FIGS. 7 to 9. The light elements have a thickness H considered in a transverse direction oriented transversely to the support 11 fastened to the support surface 11a via a fastening element 17.

In one example, the fastening element 17 is at least partially transparent to the light emitted from the light emission part of the light elements 13.

In another example that can be combined with the previous one, the fastening element 17 comprises a set of metal particles coated in an electrically insulating material adapted so that the electrically insulating material is capable of varying between a first state of electrical insulation in which the electrically insulating material does not undergo collapsing pressure and where a majority of the metal particles do not touch each other and a second state of anisotropic electrical conductivity in which a majority of the metal particles are in electrical contact under the effect of a collapsing pressure applied in the transverse direction for example via or at the level of the second electrode 13e described below.

In another example that can be combined with the previous ones, the fastening element 17 is an adhesive having properties of transparency for the light emitted by the light emission part of the light element 13 fastened by said fastening element 17. Said adhesive can, for example, contain carbon nanotubes or even be a pressure or temperature sensitive adhesive or a photonic adhesive.

In another example that can be combined with the previous ones, the fastening element 17 is electrically conductive.

The light element(s) 13 comprise at least one first electrode 13d, at least one second electrode 13e electrically insulated from the first electrode 13d, and at least one light emission part capable of emitting light when a current passes through the light emission part and comprise at least one light-emitting diode 15.

Said light-emitting diode may be wire-shaped having micrometric or even nanometric dimensions and whose main axis of extension is overall parallel to the transverse direction. Said light-emitting diode may also be of the two-dimensional type with a micrometric height. In one example, at least two light-emitting diodes 15 are arranged in the light emission part of at least one of the light elements 13. The two light-emitting diodes can then be configured to emit two light radiations having different wavelengths. In another example, at least one of the light-emitting diodes of the light emission part of at least one of the light elements 13 is surrounded at least in part by photoluminescent materials capable of transforming the light radiation emitted by the corresponding light-emitting diode.

In one example, illustrated in FIG. 2, the second electrode 13e of at least one of the light elements 13 is arranged projecting from the light element 13. This is advantageous for example when the fastening element 17 comprises metal particles. Thus the pressure is applied to the light element 13 and therefore to the second electrode 13e which in turn presses on the metal particles which thus touch each other and create an electrical contact in particular between the support 11 and the second electrode 13e in an anisotropic and localized manner.

In one example, the light element(s) 13 are obtained on an external support distinct from the support 11 prior to a transfer of said light elements 13 towards said support 11. This is advantageous because very often the light elements 13 require specific formation conditions such as high temperatures above 500° C. which could damage the support 11.

The device also comprises a plurality of primary conductive elements 22 electrically insulated from each other. At least one of the primary conductive elements 22 electrically connects at least the second electrode 13e. In the case where several light elements 13 are formed, the primary conductive elements 22 electrically connect the second electrodes 13e of at least two light elements 13 to each other.

The device further comprises a plurality of secondary conductive elements 12 electrically insulated from each other and electrically insulated from the primary conductive elements 22. At least one of the secondary conductive elements 12 electrically connects, that is to say is electrically connected to, at least said first electrode 13d. In the case where the optoelectronic device 10 comprises several light elements 13, the secondary conductive elements 12 can electrically connect the first electrodes 13d of at least two light elements 13 to each other.

Throughout the text, by “electrically connect” it should be understood “connected directly or indirectly via one or several layers”.

In an implementation illustrated in FIGS. 1 to 4, all or part of the primary conductive element 22 is formed on the support surface 11a.

In one example, at least one of the primary conductive elements 22 is transparent. This has the advantage of enabling an emission towards the support. If the fastening element 17 and the support 11 are at least partially transparent to the light emitted by the light element 13, then the light emission can be diffused through the support 11.

The primary and secondary conductive elements 12, 22 can be formed entirely or in part, for example, by photolithography such as adaptive photolithography and/or by etching then by vacuum or wet deposition methods of metals such as, for example, copper or titanium, silver, aluminum or even tungsten alloys.

The light element(s) 13 delimit externally, along the thickness H, at least one lateral wall 13c which extends laterally around the light element 13.

The optoelectronic device 10 further comprises at least one first electrically insulating element 16 arranged at least in part around said at least one lateral wall 13c of the light element 13. The first electrically insulating element 16 is also arranged between at least one of the primary conductive elements 22 and at least one of the secondary conductive elements 12 so that said at least one secondary conductive element 12 and said at least one primary conductive element 22 separated by the first electrically insulating element 16 are electrically insulated from each other. In the case where several light elements 13 are formed, the first electrically insulating element 16 is arranged between at least one part of said at least one lateral wall 13c of at least two adjacent light elements 13 disposed side by side on the support surface 11a of the support 11 so as to electrically insulate the lateral walls 13c separated by the first electrically insulating element 16 from each other.

The first electrically insulating element 16 can be formed by a resin or an oxide or an adhesive. It can also be transparent to the light radiation emitted by the light element(s) 13 which allows obtaining a light emission towards the outer side of the substrate oriented on the support surface 11a side. The first electrically insulating element 16 also allows mechanically protecting the light elements 13. This implementation is advantageous because it allows having the secondary conductive elements 12 and the primary conductive elements 22 disposed on two different planes, for example parallel to the support surface 11a, which limits short-circuits and facilitates the contact recovery.

For at least one of the light elements 13, at least one first connecting portion 12a of the secondary conductive element 12 corresponding to one of the light elements 13 is formed in all or part of a first imprint 30 obtained in the first electrically insulating element 16. The first imprint 30 can be obtained in part by adaptive photolithography and etching for example. At least one part of the first imprint 30 is superimposed on the first electrode 13d. This part of the first imprint 30 superimposed on the first electrode 13d is preferably formed by adaptive photolithography. Thus, when at least the first connecting portion 12a of the secondary conductive element 12 is formed in the first imprint 30 then it is in contact with the first electrode 13d. An advantage is that, even if one of the light elements 13 has a certain positioning fault, for example resulting from a slight involuntary offset during a previous phase of transfer of this light element 13 on the support 11, this offset is compensated by the adaptation of the adaptive photolithography parameters to the actual parameters of the light element 13 and this light element 13 may be functionally connected.

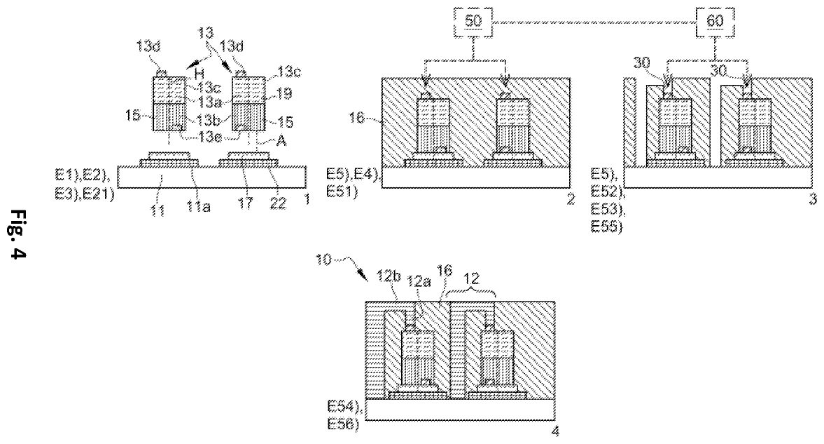

In an example illustrated in FIG. 4, at least one additional part of the secondary conductive element 12 is formed in the first electrically insulating element 16 for example by etching and filling a via to electrically connect another part of the secondary conductive element 12 which would be arranged on the support surface 11a. This architecture is advantageous in that subsequent processing is limited.

In an example illustrated in FIGS. 1 to 4 and 6 to 8, all or part of the primary conductive element 22 is formed on the support surface 11a.

In another example which can be combined with the previous one and which is illustrated in FIGS. 1 to 4 and 7-8, the second electrode 13e of at least one of the light elements 13 is formed on the support surface 11a side. This allows reducing the time when adaptive photolithography is used.

In an additional example that can be combined with the other examples, the first connecting portions 12a of the secondary conductive elements 12 formed in the first corresponding imprints 30, have respective spatial configurations which differ from one first connecting portion 12a to another. The spatial configuration adopted by each first connecting portion 12a thus depends on the positioning of the light elements 13 with which it is in contact relative to the support 11. The establishment of electrical contact on one of the first and/or second electrodes 13d, 13e of light element(s) 13 is therefore advantageously carried out even if the positioning of these light elements differs from an initially envisaged predetermined position. This is advantageously achieved thanks to the adaptive photolithography technique. The positioning constraints are thus relieved.

An advantage of the optoelectronic device of the disclosure is that the secondary conductive elements 12 and the primary conductive elements 22 are electrically insulated in a robust and economical manner. This advantage can be obtained even if the topography of the light elements 13 is higher than about ten microns.

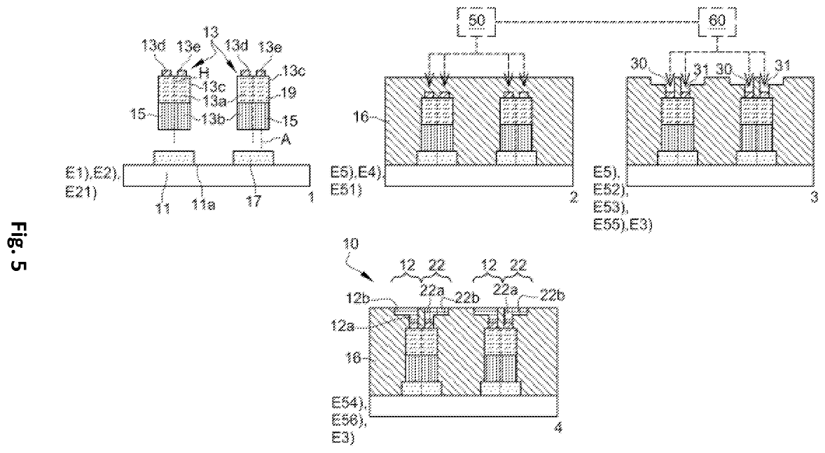

In an example illustrated in FIGS. 5, 6 and 9, the second electrode 13e of at least one of the light elements 13 is formed on the side of an upper surface of the first electrically insulating element 16 arranged opposite to the support surface 11a of the support 11 in the transverse direction. The first and second electrodes can thus be arranged at the same time on the upper surface of the first electrically insulating element 16. This advantageously allows protecting the light elements 13. This also allows optimizing the spacing between the light elements 13 while guaranteeing a recovery of electrical contact on the electrodes even if the location of the light element is different from that initially envisaged to constitute for example the display matrix.

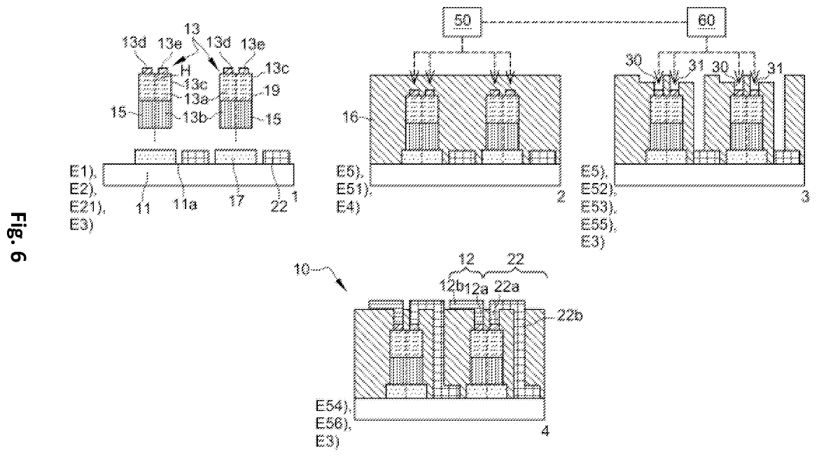

In general and as illustrated in FIG. 6 or 9, if the secondary conductive elements 12 and the primary conductive elements 22 can all be formed entirely or in part on or from the upper surface of the first electrically insulating element 16. In that case, at the level where the secondary conductive elements 12 and the primary conductive elements 22 intersect, any of them must punctually overlap each other. It will then be necessary to provide for electrical insulator at the level of these overlaps.

In an example illustrated in FIGS. 5 and 6, which can for example be combined with the previous one, at the level of at least one of the light elements 13, all or part of the primary conductive element 22 is formed in a second imprint 31 obtained for example by photolithography and/or at least in part by photolithography and etching in the first electrically insulating element 16 and more particularly on the side of the upper surface of the first electrically insulating element 16. At least one part of the second imprint 31 is superimposed on the location of the second electrode 13e by adaptive photolithography so that a second connecting portion 22a of the primary conductive element 22 is in physical and electrical contact with the second electrode 13e. This architecture is advantageous in that it avoids the need to create vias over more than 30 micrometers in thickness through the first electrically insulating element 16. In combination with the previous example, a part of the primary conductive element 22 can be formed on the side of the upper face of the first electrically insulating element 16 in electrical connection with the second electrode 13e of at least one light element 13 but another part of the primary conductive element 22 is formed for example as shown in FIG. 6.3 with an etching of the first electrically insulating element 16 opening onto another part of the primary conductive element 22 arranged on the support surface 11a.

The same principle is also possible for the implementation of the secondary conductive element 12 as shown in FIG. 4.

In one implementation of the optoelectronic device 10, the light element(s) 13 include an upper portion 13b comprising the light emission part and a lower portion 13a including a control device 19 connected to at least one of the light-emitting diodes 15 of the light emission part. The control device 19 is capable of modulating at least one emission parameter of the light emission part. The control device 19 can thus comprise one or several transistors of CMOS and/or bipolar and/or thin film transistor (TFT) type technology or any other technology such as GaN or even GaN on Si. It can also include memories or passive components. It is for example powered by a voltage or a current coming from the primary and secondary conductive elements 12, 22 connected thereto, or only one of them. According to this implementation, the lateral wall 13c extends laterally around at least all or part of the lower portion 13a and the upper portion 13b.

In a further implementation illustrated in FIGS. 1 to 9, at least one or each secondary conductive element 12 comprises at least one first main portion 12b in physical and electrical contact with the first connecting portion 12a, the first main portion 12b being a member dissociated from the first connecting portion 12a. In combination or not, at least one or each primary conductive element 22 comprises at least one second main portion 22b in contact with the second connecting portion 22a, the second main portion 22b being a member dissociated from the second connecting portion 22a. To lower the production costs, the first and second main portions, 12b, 22b are preferably made using a technique different from the first and second connecting portions 12a, 22a. Thus the first and second main portions, 12b, 22b can be formed by conventional photolithography because they can be arranged without strong constraints vis-à-vis the placement of the light elements 13. On the contrary, the first and second connecting portions 12a, 22a must be accurately formed in a suitable manner at the current or actual location of the first and second electrodes 13d, 13e to electrically connect the first and second electrodes 13d, and 13e once the light elements 13 are fastened to the support 11.

In an example illustrated in FIG. 5, at least one part of a portion, selected from the first main portion 12b of one of the secondary conductive elements 12 or the second main portion 22b of one of the primary conductive elements 22, is formed on the upper surface of the first electrically insulating element 16.

The disclosure also concerns a method for manufacturing an optoelectronic device 10 for a light display.

The manufacturing method illustrated in FIGS. 1 to 6 comprises the following steps:
E1) provide a support 11 delimiting a support surface 11a;
E2) form at least one light element 13 having a thickness H considered in a transverse direction oriented transversely to the support 11, fastened to the support surface 11a via a fastening element 17, and comprising at least one first electrode 13d and at least one second electrode 13e electrically insulated from each other, in which said at least one light element 13 delimits externally, along the thickness H, at least one lateral wall 13c which extends laterally around the light element 13, said at least one light element 13 formed in step E2) including at least one light emission part capable of emitting light when a current passes through the light emission part and comprising at least one light-emitting diode 15;
E3) form a plurality of primary conductive elements 22 electrically insulated from each other, at least one of the primary conductive elements being electrically connected to at least said second electrode 13e;
E4) form at least one first electrically insulating element 16 arranged at least in part around said at least one lateral wall 13c,
E5) form a plurality of secondary conductive elements 12, electrically insulated from each other, at least one of the secondary conductive elements 12 being electrically connected to at least said first electrode 13d.

At the end of step E5) the first electrically insulating element 16 is arranged between at least one of the primary conductive elements 22 and at least one of the secondary conductive elements 12 so that said at least one secondary conductive element 12 and said at least one primary conductive element 22 separated by the first electrically insulating element 16 are electrically insulated from each other.

In this method, step E5) comprises the following sub-steps:
E51) tracking of a current or actual position of the first electrode 13d of said at least one light element 13 by a tracking device 50, such as a linear camera of the TDI type;
E52) determination of local photolithography parameters by an adjustment device 60 for example comprising piezoelectric elements taking into account the current or actual position of the first electrode 13d of the element light 13 determined in step E51);
E53) formation, using at least one photolithography beam adjusted at least in part with the local photolithography parameters determined in step E52), of all or part of the first imprint 30, delimited directly or indirectly via resin etching and/or exposure phases, in the first electrically insulating element 16, such that at least one part of the first imprint 30 is superimposed on the first electrode 13d;
E54) formation of at least one first connecting portion 12a of the secondary conductive element 12 in said first imprint 30 so that at least the first connecting portion 12a of said at least one secondary conductive element 12 is in physical and electrical contact with the first electrode 13d. Steps E51) to E53) are compatible with adaptive photolithography steps.

In one implementation of the method, step E5) comprises a sub-step E55) consisting in forming a first main imprint in the first electrically insulating element 16 and opening onto the first imprint 30, by a method different from the method used in steps E51) to E53).

In an additional implementation, step E5) comprises an additional sub-step E56) consisting in forming in the first main imprint a first main portion 12b of the secondary conductive element 12, in physical and electrical contact with the first connecting portion 12a.

In an additional implementation, step E2) includes a sub-step E21) consisting in obtaining the light elements 13 on an external support different from the support 11 prior to a transfer of said light elements 13 towards the support surface 11a of the support 11 by fastening thanks to the fastening element 17.

An advantage of the manufacturing method of the disclosure is that its implementation can be carried out with techniques which do not require high temperature and pressure. These techniques are also suitable for applications on large surfaces, which is advantageous for producing display devices of large dimension, for example greater than that of a silicon wafer.

An additional advantage of this implementation is that the use of the adaptive photolithography method allows locally correcting, at the level of the first and second connecting portions, a possible offset in placement of the light element 13 occurred during a previous transfer phase. The cost of using adaptive photolithography is therefore reduced and the manufacturing time is limited.

1. An optoelectronic device for a light display, the optoelectronic device comprising:
a support delimiting a support surface;
at least one light element having a thickness (H) considered in a transverse direction oriented transversely to the support, fastened to the support surface via a fastening element, and comprising at least one first electrode, at least one second electrode electrically insulated from the first electrode, and at least one light emission part capable of emitting light when a current passes through the light emission part and comprising at least one light-emitting diode;
a plurality of primary conductive elements electrically insulated from each other, at least one of the primary conductive elements electrically connecting at least said second electrode; and
a plurality of secondary conductive elements electrically insulated from each other and electrically insulated from the primary conductive elements, at least one of the secondary conductive elements electrically connecting at least said first electrode;
wherein each light element delimits externally, along the thickness (H), at least one lateral wall which extends laterally around the light element;
the optoelectronic device comprising at least one first electrically insulating element arranged at least in part around said at least one lateral wall of the light element and between at least one of the secondary conductive elements and at least one of the primary conductive elements so that said at least one secondary conductive element and said at least one primary conductive element separated by the first electrically insulating element are electrically insulated from each other, wherein for said at least one light element, at least one first connecting portion of at least one of the secondary conductive elements corresponding to said light element is formed in all or part of a first imprint obtained in the first electrically insulating element, at least one part of the first imprint being superimposed on the first electrode so that at least the first connecting portion of the secondary conductive element is in contact with the first electrode.

2. The optoelectronic device according to claim 1, wherein the support, at least one of the primary conductive elements and the fastening element are at least partially transparent to the light emitted by the light emission part of the light elements.

3. The optoelectronic device according to claim 1, wherein said light element includes an upper portion comprising the light emission part and a lower portion including a control device connected to at least one of the light-emitting diodes of the light emission part and capable of modulating at least one emission parameter of the light emission part.

4. The optoelectronic device according to claim 1, wherein the light-emitting diode is wire-shaped with micrometric dimensions and whose main axis of extension (A) is overall parallel to said transverse direction.

5. The optoelectronic device according to claim 3, wherein the lateral wall extends laterally around at least the lower portion and the upper portion.

6. The optoelectronic device according to claim 1, wherein all or part of the primary conductive element is formed on the support surface.

7. The optoelectronic device according to claim 6, wherein the second electrode of at least one of the light elements is formed on the support surface side.

8. The optoelectronic device according to claim 1, wherein the first imprint is formed by an adaptive photolithography method.

9. The optoelectronic device according to claim 1, wherein the plurality of light elements are fastened to the support face, wherein the first connecting portions of the secondary conductive elements formed in the first corresponding imprints, have respective spatial configurations which differ from one first connecting portion to another and wherein the spatial configuration adopted by each first connecting portion depends on the positioning of the light element with which it is in contact relative to the support.

10. The optoelectronic device according to claim 1, wherein at the level of at least one of the light elements, all or part of the primary conductive element is formed in a second imprint obtained in the first electrically insulating element, at least one part of the second imprint being superimposed on the location of the second electrode so that a second connecting portion of the primary conductive element is in contact with the second electrode.

11. The optoelectronic device according to claim 10, wherein all or part of the second imprint is formed by an adaptive photolithography method.

12. The optoelectronic device according to claim 10, wherein for the different light elements of the plurality, the second connecting portions of the primary conductive elements have respective spatial configurations which differ from one second connecting portion to another and wherein the spatial configuration adopted by each second connecting portion depends on the positioning of the light element with which it is in contact relative to the support.

13. The optoelectronic device according to claim 10, wherein each secondary conductive element comprises at least one first main portion in contact with the first connecting portion, the first main portion being a member dissociated from the first connecting portion, and wherein each primary conductive element comprises at least one second main portion in contact with the second connecting portion, the second main portion being a member dissociated from the second connecting portion.

14. The optoelectronic device according to claim 13, wherein at least one part of a portion selected from the group consisting of the first main portion of one of the secondary conductive elements and the second main portion of one of the primary conductive elements is formed on an upper surface of the first electrically insulating element arranged opposite to the support surface of the support in the transverse direction.

15. The optoelectronic device according to claim 1, wherein at least one part of one of the primary conductive elements is arranged in contact with the support surface of the support.

16. The optoelectronic device according to claim 1, wherein the fastening element comprises a set of metal particles coated in an electrically insulating material adapted so that the electrically insulating material is capable of varying between a first state of electrical insulation in which the electrically insulating material does not undergo collapsing pressure and where a majority of the metal particles do not touch each other and a second state of anisotropic electrical conductivity in which a majority of the metal particles are in electrical contact under the effect of a collapsing pressure applied in the transverse direction.

17. The optoelectronic device according to claim 1, wherein the fastening element is an adhesive having properties of transparency for the light emitted by the light emission part of the light element fastened by said fastening element.

18. The optoelectronic device according to claim 1, wherein the light element(s) are obtained on an external support different from the support prior to a transfer of said light elements towards the support surface of the support.

19. The optoelectronic device according to claim 1, wherein the fastening element is electrically conductive.

20. The optoelectronic device according to claim 1, wherein said at least one second electrode is arranged projecting from the light element.

21. A method for manufacturing an optoelectronic device for a light display, the manufacturing method including the following steps:
E1) provide a support delimiting a support surface;
E2) form at least one light element having a thickness (H) considered in a transverse direction oriented transversely to the support, fastened to the support surface via a fastening element, and comprising at least one first electrode and at least one second electrode electrically insulated from each other, in which said at least one light element delimits externally, along the thickness (H), at least one lateral wall which extends laterally around the light element, said at least one light element formed in step E2) including at least one light emission part capable of emitting light when a current passes through the light emission part and comprising at least one light-emitting diode;
E3) form a plurality of primary conductive elements electrically insulated from each other, at least one of the primary conductive elements being electrically connected to at least said second electrode;
E4) form at least one first electrically insulating element arranged at least in part around said at least one lateral wall, and
E5) form a plurality of secondary conductive elements, electrically insulated from each other, at least one of the secondary conductive elements being electrically connected to at least said first electrode;
the manufacturing method wherein at the end of step E5) the first electrically insulating element is arranged between at least one of the primary conductive elements and at least one of the secondary conductive elements so that said at least one secondary conductive element and said at least one primary conductive element separated by the first electrically insulating element are electrically insulated from each other and wherein step E5) comprises the following sub-steps:
E51) tracking of a current position of the first electrode of said at least one light element by a tracking device;
E52) determination of local photolithography parameters by an adjustment device taking into account the current position of the first electrode of the light element determined in step E51);
E53) formation, using at least one photolithography beam adjusted at least in part with the local photolithography parameters determined in step E52), of all or part of a first imprint in the first electrically insulating element, such that at least one part of the first imprint is superimposed on the first electrode; and
E54) formation of at least one first connecting portion of the secondary conductive element in said first imprint so that at least the first connecting portion of said at least one secondary conductive element is in contact with the first electrode.

22. The manufacturing method according to claim 21, wherein step E5) comprises a sub-step E55) including forming a first main imprint in the first electrically insulating element and opening onto the first imprint, by a method different from the method used in steps E51) to E53).

23. The manufacturing method according to claim 22, wherein step E5) comprises an additional sub-step E56) including forming in the first main imprint a first main portion of the secondary conductive element, in contact with the first connecting portion.

24. The manufacturing method according to claim 21, wherein step E2) comprises a sub-step E21) including obtaining said at least one light element on an external support different from the support prior to a transfer of said light element to the support surface of the support by fastening thanks to the fastening element.

25. The optoelectronic device according to claim 8, comprising a plurality of light elements.
